(19) United States
(12) Patent Application Publication
(10) Pub. No.: US 2026/0150517 A1
(43) Pub. Date: May 28, 2026

(54) DISPLAY PANEL AND DISPLAY DEVICE

(71) Applicants: Mianyang HKC Optoelectronics Technology Co.,Ltd., MIANYANG (CN); HKC CORPORATION LIMITED, SHENZHEN (CN)

(72) Inventors: Yangling TANG, MIANYANG (CN); Xiufeng ZHOU, MIANYANG (CN); Qin LIANG, MIANYANG (CN); Zhisheng XIE, MIANYANG (CN); Haijiang YUAN, MIANYANG (CN)

(73) Assignees: Mianyang HKC Optoelectronics Technology Co.,Ltd., MIANYANG (CN); HKC CORPORATION LIMITED, SHENZHEN (CN)

(21) Appl. No.: 19/383,660

(22) Filed: Nov. 9, 2025

(30) Foreign Application Priority Data
Nov. 28, 2024 (CN) 202411731991.0

(51) Int. Cl. H10K 59/122

(52) U.S. Cl. CPC H10K 59/122

(57) ABSTRACT

A display panel and a display device are provided. The display panel includes a driving substrate, a planarization layer, a pixel defining layer defining a pixel region, sub-pixels disposed in the pixel region, and a spacer structure disposed on the pixel defining layer. The sub-pixels include first sub-pixels, second sub-pixels, and third sub-pixels disposed in a first direction and a second direction. In the second direction, adjacent two of the second sub-pixels in a same pixel column form a pixel pair. Within the pixel pair, the spacer structure includes two first sub-spacer structures and two sub-second spacer structures. The two second sub-spacer structures are connected to the two first sub-spacer structures to interconnect connection holes of the two first sub-spacer structures. The anode via hole corresponding to each of the second sub-pixels in the pixel pair is located between the two second sub-spacer structures.

### CROSS-REFERENCE TO RELATED APPLICATIONS

This application claims priority to Chinese Patent Application No. 202411731991.0, filed on Nov. 28, 2024 in the National Intellectual Property Administration of China, the contents of which are herein incorporated by reference in their entireties.

### TECHNICAL FIELD

Some embodiments of the present disclosure relate to the field of optical display technology, and in particular to a display panel and a display device.

### BACKGROUND

For current organic light-emitting diode (OLED) display panels, a fine metal mask is used to deposit an OLED light-emitting unit during manufacture. The fine metal mask is expensive, leading to high costs when developing new products. Moreover, a bridged area in the fine metal mask openings may limit an effective deposition area of the pixel light-emitting region, which is unfavorable for improving an aperture ratio.

### SUMMARY OF THE DISCLOSURE

Some embodiments of the present disclosure may provide a display panel. The display panel may include a driving substrate, a planarization layer disposed on the driving substrate, a pixel defining layer disposed on the planarization layer and defining a pixel region, a plurality of anodes disposed in the pixel region, a plurality of sub-pixels disposed in the pixel region, and a spacer structure disposed on the pixel defining layer. A plurality of anode via holes may be defined on the planarization layer in a radial direction of the pixel region. Each of the plurality of anodes may extend toward a corresponding one of the plurality of anode via holes. Each of the plurality of anodes may be electrically connected to the driving substrate through the corresponding one of the plurality of anode via holes. The plurality of sub-pixels may include first sub-pixels, second sub-pixels, and third sub-pixels. The first sub-pixels, the second sub-pixels, and the third sub-pixels may be disposed in a first direction and a second direction. The spacer structure may protrude toward a side away from the driving substrate and may be configured to space the first sub-pixels, the second sub-pixels, and the third sub-pixels apart from each other. In the second direction, adjacent two of the second sub-pixels in a same pixel column may form a pixel pair. In the pixel pair, the anode via hole corresponding to any one of the second sub-pixels may be located on a side of the one of the second sub-pixels that is adjacent to the other one of the second sub-pixels. Within the pixel pair, the spacer structure may include two first sub-spacer structures and two second sub-spacer structures. Each of the two first sub-spacer structures may be disposed on an outer peripheral side of a corresponding one of the two second sub-pixels. A connection hole may be defined on a side of each of the two first sub-spacer structures that is adjacent to the corresponding anode via hole. The two second sub-spacer structures may be connected to the two first sub-spacer structures to interconnect the connection holes of the two first sub-spacer structures. The anode via hole corresponding to each of the second sub-pixels in the pixel pair may be located between the two second sub-spacer structures.

Some embodiments of the present disclosure may provide a display device. The display device may include the display panel mentioned above and a circuit board electrically connected to the display panel.

Some embodiments of the present disclosure may provide a display panel. The display panel may include a driving substrate, a planarization layer disposed on the driving substrate, a pixel defining layer disposed on the planarization layer and defining a pixel region, a plurality of anodes disposed in the pixel region, a plurality of sub-pixels disposed in the pixel region, and a spacer structure disposed on the pixel defining layer. A plurality of anode via holes may be defined on the planarization layer in a radial direction of the pixel region. Each of the plurality of anodes may extend toward a corresponding one of the plurality of anode via holes. Each of the plurality of anodes may be electrically connected to the driving substrate through the corresponding one of the plurality of anode via holes. The plurality of sub-pixels may include first sub-pixels, second sub-pixels, and third sub-pixels. The first sub-pixels, the second sub-pixels, and the third sub-pixels may be disposed in a first direction and a second direction. The spacer structure may protrude toward a side away from the driving substrate and may be configured to space the first sub-pixels, the second sub-pixels, and the third sub-pixels apart from each other. In the pixel pair, portions of the pixel region where the two second sub-pixels are located may be in communication with each other and the spacer structure located on both sides of the anode via holes corresponding to the two second sub-pixels may be substantially linear.

### BRIEF DESCRIPTION OF THE DRAWINGS

The accompanying drawings, which are incorporated into and constitute a part of this specification, illustrate some embodiments consistent with the present disclosure and, together with the description, serve to explain the principles of the present disclosure. It is evident that the drawings in the following description represent only some embodiments of the present disclosure. Those skills in the art may derive additional drawings from the accompanying drawings without creative effort.

FIG. 1 is a schematic structural sectional view of a display panel according to some embodiments of the present disclosure, where a pixel defining layer in the display panel is made of an organic material.

FIG. 2 is a schematic structural sectional view of a display panel according to some embodiments of the present disclosure, where a pixel defining layer in the display panel is made of an inorganic material.

FIG. 3 is a schematic structural plan view of a display panel according to some embodiments of the present disclosure.

FIG. 4 is a schematic structural plan view of a first sub-pixel, a second sub-pixel, and a third sub-pixel forming a virtual rhombus in a display panel according to some embodiments of the present disclosure.

FIG. 5 is a schematic structural plan view of a pixel pair according to some embodiments of the present disclosure.

FIG. 6 is a schematic structural sectional view at A-A in FIG. 5.

FIG. 7 is a schematic structural sectional view at B-B in FIG. 5.

FIG. 8 is a schematic structural sectional view of a display device according to some embodiments of the present disclosure.

### DETAILED DESCRIPTION

Some exemplary embodiments of the present disclosure will now be described more fully with reference to the accompanying drawings. However, the exemplary embodiments may be implemented in various forms and should not be construed as limited to the examples set forth herein. Rather, these embodiments are provided so that the present disclosure will be more thorough and complete, and will fully convey the concepts of the exemplary embodiments to those skills in the art.

Furthermore, the described features, structures, or characteristics may be combined in any suitable manner in one or more embodiments. In the following description, numerous specific details are provided to facilitate a thorough understanding of some embodiments of the present disclosure. However, those skills in the art may recognize that the technical solutions of the present disclosure may be practiced without one or more of the specific details, or other methods, components, devices, steps, etc., may be employed. In other instances, well-known methods, devices, implementations, or operations are not shown or described in detail to avoid obscuring aspects of the present disclosure.

The present disclosure will be further described in detail below with reference to the accompanying drawings and specific embodiments. It should be noted that the technical features involved in the various embodiments of the present disclosure described below may be combined as long as they do not conflict with each other. The embodiments described with reference to the accompanying drawings are exemplary and are intended to explain the present disclosure, but should not be construed as limiting the present disclosure.

It should be noted that, the term “a plurality of” herein refers to two or more. The term “and/or” describes the association relationship of associated objects, indicating that there may be three relationships. For example, “A and/or B” may represent: A alone, both A and B, or B alone. The character “/” generally indicates that the associated objects are in an “or” relationship.

Furthermore, it is to be understood that the use of the term “substantially” herein, unless otherwise defined with respect to a specific context, with respect to a numeric quantity or otherwise quantifiable relationship, e.g., perpendicularity or parallelism, is to be understood as indicating that quantity +−10%. Thus, for example, lines that are substantially perpendicular to one another may be at angles between 81° and 99° to one another. In a further example, dimensions that are substantially between 1 mm and 3 mm, for example, may range from 0.9 mm to 3.3 mm. In another example, an angle that is substantially in the range of 1 to 1.1 radians may be between 0.9 radians and 1.21 radians.

For current organic light-emitting diode (OLED) display panels, a fine metal mask may be used to deposit an OLED light-emitting unit during manufacture. The fine metal mask is expensive, leading to high costs when developing new products. Moreover, a bridged area in the fine metal mask openings may limit an effective deposition area of the pixel light-emitting region, which is unfavorable for improving an aperture ratio.

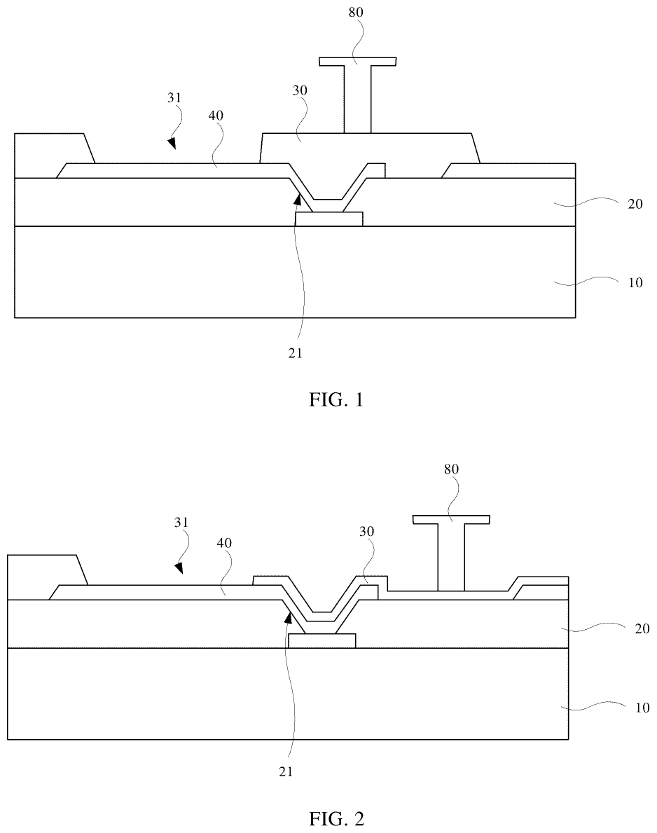

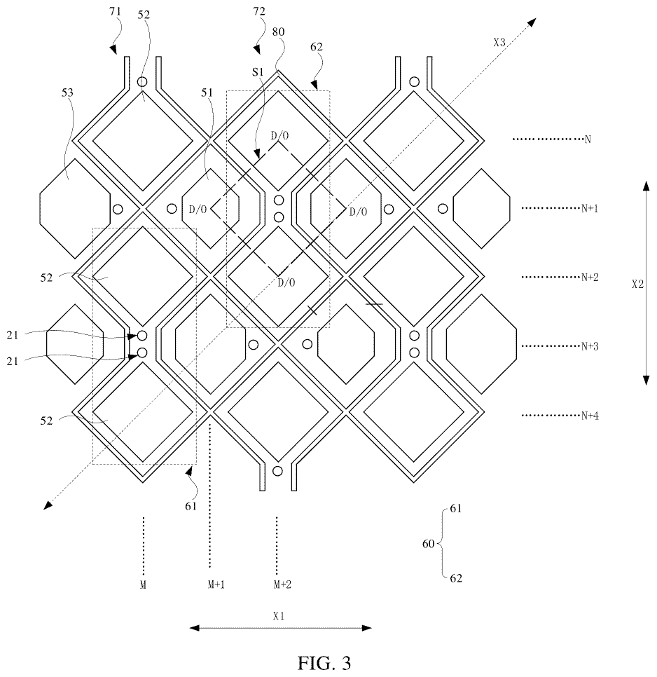

In order to solve the aforementioned technical problems, some embodiments of the present disclosure may provide a display panel. As shown in FIGS. 1-3, FIG. 1 is a schematic structural sectional view of a display panel according to some embodiments of the present disclosure, where a pixel defining layer in the display panel is made of an organic material, FIG. 2 is a schematic structural sectional view of a display panel according to some embodiments of the present disclosure, where a pixel defining layer in the display panel is made of an inorganic material, and FIG. 3 is a schematic structural plan view of a display panel according to some embodiments of the present disclosure.

In some embodiments, as shown in FIGS. 1-3, the display panel may include a driving substrate 10, a planarization layer 20, a pixel defining layer 30, a plurality of anodes 40, a plurality of sub-pixels 50, and a spacer structure 80. The planarization layer 20 may be disposed on the driving substrate 10. The pixel defining layer 30 may be disposed on the planarization layer 20 and define a pixel region 31. A plurality of anode via holes 21 may be defined on the planarization layer 20 in a radial direction of the pixel region 31. Each anode 40 may be disposed in the pixel region 31 and may extend toward a corresponding one of the anode via holes 21. Each anode 40 may be electrically connected to the driving substrate 10 through the corresponding anode via hole 21. The sub-pixels 50 may be disposed in the pixel region 31. The sub-pixels 50 may include first sub-pixels 51, second sub-pixel 52, and third sub-pixels 53. The first sub-pixels 51, the second sub-pixels 52, and the third sub-pixels 53 may be disposed or arranged in a first direction X1 and a second direction X2. In a diagonal direction X3 between the first direction X1 and the second direction X2, the second sub-pixels 52 and the first sub-pixels 51 may be arranged alternately at intervals, and the second sub-pixels 52 and the third sub-pixels 53 may be arranged alternately at intervals. The spacer structure 80 may be disposed on the pixel defining layer 30 and may protrude toward a side of the pixel defining layer 30 away from the driving substrate 10. The spacer structure 80 may be configured to space the first sub-pixels 51, the second sub-pixels 52, and the third sub-pixels 53 apart from each other. In the second direction X2, adjacent two of the second sub-pixels 52 in a same sub-pixel column may form a pixel pair 60. The anode via hole 21 corresponding to any one of the second sub-pixels 52 in the pixel pair 60 may be located on a side of the one of the second sub-pixels 52 that is adjacent to the other one of the second sub-pixels 52 in the pixel pair 60. Within the pixel pair 60, the spacer structure 80 may include two first sub-spacer structures 81 and two second sub-spacer structures 82. The two first sub-spacer structures 81 may be disposed respectively on outer peripheral sides of the two second sub-pixels 52. That is, each of the two first sub-spacer structures 81 may be disposed on an outer peripheral side of a corresponding one of the two second sub-pixels 52. A connection hole 83 may be defined on a side of each of the two first sub-spacer structures 81 that is adjacent to the corresponding anode via hole 21. The two second sub-spacer structures 82 may be connected to the two first sub-spacer structures 81 to allow the connection holes 83 of the first sub-spacer structures 81 to be in communication with each other. The anode via hole 21 of each of the second sub-pixels 62 in the pixel pair 60 may be located between the two first spacer structures 81. The anode via hole 21 corresponding to each of the second sub-pixels 62 in the pixel pair 60 may be located between the two second sub-spacer structures 82.

That is, the driving substrate 10 may be configured to drive the display panel. In some embodiments, each anode 40 may be electrically connected to the driving substrate 10, and the sub-pixels 50 may be driven by the driving substrate 10 to emit light. The first sub-pixels 51, the second sub-pixels 52, and the third sub-pixels 53 may be disposed in the first direction X1 and the second direction X2, and may be individually encapsulated by the spacer structure 80. In the second direction X2, any two second sub-pixels 52 in the same sub-pixel column may form the pixel pair 60. In the pixel pair 60, the anode via hole 21 corresponding to any one of the second sub-pixels 52 may be located on a side of the one of the second sub-pixels 52 that is adjacent to the other one of the second sub-pixels 52. No spacer structure 80 may be disposed between the two corresponding anode via holes 21 in the pixel pair 60. The anode via hole 21 corresponding to each of the second sub-pixels 62 in the pixel pair 60 may be disposed between the two second sub-spacer structures 82 such that the two first sub-spacer structures 81 may be in communication with each other through the arrangement of the two second sub-spacer structures 82. The above design may enable the second sub-spacer structures 82 to be arranged in parallel with the second direction X2. During a deposition process of the display panel, since a deposition direction may be perpendicular to the second direction X2, a shielding area of the second sub-spacer structures 82 to a deposition source may be reduced during the deposition, thereby allowing an increased spacing between the sub-pixels 50 and further an increased aperture ratio of the sub-pixels 50.

In some embodiments, during the deposition of a light-emitting material, since the deposition source may generate a deposition cloud along a long-side direction (referred to as the Nozzle direction hereinafter), and due to the absence of a restriction plate that limits the angle, a deposition angle θ1 may be relatively large. In contrast, in a moving direction (referred to as the Scan direction hereinafter), a deposition angle θ2 of the material may be controlled by the restriction plate. Due to the difference between the deposition angles θ1 and θ2, the influence on an a-value in the Nozzle/Scan direction may differ. Since a region defined by the a-value may have non-uniform film thickness and thus may not be usable for light emission, the pixel defining layer (PDL) opening may have to avoid the region. A gap between the pixels (referred to as the PDL-Gap) may have to be greater than 2(a+b), where b may represent half the width of the spacer structure 80. Currently, in order to improve the display performance and lifespan of the pixels, OLED mobile products may generally adopt a diamond or diamond-like arrangement of pixels. Therefore, the spacer structure 80 may need to form a separate barrier around each pixel. As a result, an open hole (OH) circuit structure may adopt a diagonal layout in the pixel arrangement. Since the deposition angle θ2 may be limited by the restriction plate and the second sub-spacer structure 82 may be disposed parallel to the second direction X2, the second sub-spacer structure 82 may be perpendicular to the Scan direction of the deposition source. Under the same deposition incident angle, both an emission layer and a cathode of the sub-pixels 50 may be more effectively deposited on the pixel defining layer 30, thereby reducing the a-value and increasing the PDL-Gap to improve the pixel aperture ratio.

In some embodiments, as shown in FIG. 1 and FIG. 2, the driving substrate 10 may include a flexible substrate and a driving circuit. The flexible substrate may be a glass flexible substrate or an organic flexible substrate. The driving circuit may be a thin film transistor (TFT) circuit layer. The TFT circuit layer may be configured to drive the light-emitting layer of the OLED. In some embodiments, the TFT circuit layer may include a plurality of driving circuit units arranged in an array. Each driving circuit unit may include a TFT device and a capacitor. Each driving circuit unit may correspond to one anode 40 and one organic light-emitting layer. The TFT device may be a low temperature poly-silicon (LTPS) type or a metal-oxide semiconductor (MOS) type, such as an indium gallium zinc oxide (IGZO) metal-oxide semiconductor type.

In some embodiments, a material of the planarization layer 20 may include an organic material, such as polyimide and etc.

In some embodiments, a material of the pixel defining layer 30 may include an organic material or an inorganic material. As shown in FIG. 1, the organic material may fill the anode via holes 21. As shown in FIG. 2, the inorganic material may grow according to the shape of each anode via hole 21 to form the pixel defining layer 30 that matches the anode via holes 21. The pixel defining layer 30 may extend along the anode via holes 21 and the planarization layer 20. An orthographic projection of the spacer structure 80 on the driving substrate 10 and orthographic projections of the anode via holes 21 on the driving substrate 10 may be non-overlapped or may not overlap with each other, thereby allowing the spacer structure 80 and the anode via holes 21 to be spaced apart from each other. The above design may provide better structural stability to the spacer structure 80.

In some embodiments, as shown in FIG. 1 and FIG. 2, the pixel defining layer 30 may be disposed on the planarization layer 20 at intervals. That is, portions of the pixel defining layer 30 may be spaced apart from one another on the planarization layer 20. The pixel defining layer 30 may protrude from a side of the planarization layer 20 that is away from the driving substrate 10 to form the pixel region 31. The anode via holes 21 may be located in a region covered by the pixel defining layer 30. The aperture size and the shape of each anode via hole 21 may be selected according to actual requirements.

In some embodiments, as shown in FIG. 3, the sub-pixels 50 may include red, green, and blue sub-pixels 50. The first sub-pixels 51, the second sub-pixels 52, and the third sub-pixels 53 may respectively correspond to any one of the red, green, and blue sub-pixels 50. In some embodiments, as shown in FIG. 3, the first sub-pixels 51 may be red sub-pixels 50, the second sub-pixels 52 may be green sub-pixels 50, and the third sub-pixels 53 may be blue sub-pixels 50. An area of each second sub-pixel 52 may be greater than an area of each first sub-pixel 51. An area of each third sub-pixel 53 may be greater than the area of each first sub-pixel 51. That is, a hexagonal sub-pixel with the greater area may be the third sub-pixel 53, a hexagonal sub-pixel with the smaller area may be the first sub-pixel 51, and a quadrilateral sub-pixel may be the second sub-pixel 52.

In some embodiments, as shown in FIG. 3, the first direction X1 may be a horizontal direction of the display panel, and the second direction X2 may be a vertical direction of the display panel. The diagonal direction X3 may be any direction between the first direction X1 and the second direction X2. In some embodiments, the diagonal direction X3 may be at a 45° angle relative to the first direction X1.

In some embodiments, as shown in FIG. 3, in the display panel, center points O of one first sub-pixel 51, two second sub-pixels 52, and one third sub-pixel 53 that are adjacent to one another may coincide with vertices D of a virtual rhombus S1. That is, the center point O of the one first sub-pixel 51, the center points O of the two second sub-pixels 52, and the center point O of the one third sub-pixel 53 may be connected in line to form one virtual rhombus S1, which may facilitate the description of spatial and structural relationships among the sub-pixels 50. In other embodiments, the first sub-pixels 51, the second sub-pixels 52, and the third sub-pixels 53 may be arranged such that the connection lines of their center points O may form a virtual hexagon, octagon, or other polygon. The corresponding diagonal direction X3 may have different inclined angles depending on the polygonal shape and may be selected according to the actual requirements.

In some embodiments, as shown in FIG. 3, the diamond or diamond-like arrangement may include: in the first direction X1, the second sub-pixels 52 may be arranged at intervals to form a first pixel row, and first sub-pixels 51 and third sub-pixels 53 may be arranged alternately at intervals to form a second pixel row. The first pixel row and the second pixel row may be alternately arranged at intervals in the second direction X2. In the second direction X2, the second sub-pixels 52 may be arranged at intervals to form a first pixel column, and the first sub-pixels 51 and the third sub-pixels 53 may be alternately arranged at intervals to form a second pixel column. The first pixel column and the second pixel column may be alternately arranged at intervals in the first direction X1. In this way, the diamond arrangement structure may be formed, which may result in a display panel with long service life and stable performance.

In some embodiments, as shown in FIG. 3, in the first direction X1, the N-th pixel row may be set to include entirely the second sub-pixels 52, and the (N+1)-th pixel row may be set to include the first sub-pixels 51 and the third sub-pixels 53 that are alternately arranged at intervals. Subsequent arrangements may follow the pattern of the N-th pixel row and (N+1)-th pixel row. In the second direction X2, the M-th pixel column may be set to include entirely the second sub-pixels 52, and the (M+1)-th pixel column may be set to include the first sub-pixels 51 and the third sub-pixels 53 that are alternately arranged at intervals. Subsequent arrangements may follow the pattern of the M-th pixel column and (M+1)-th pixel column. In this way, along the diagonal direction X3 between the first direction X1 and the second direction X2, the second sub-pixels 52 and the first sub-pixels 51 may be alternately arranged at intervals and the second sub-pixels 52 and the third sub-pixels 53 may be alternately arranged at intervals.

In some embodiments, as shown in FIG. 3, the pixel rows may extend and be arranged in the first direction X1 and the pixel columns may extend and be arranged in the second direction X2. Any two second sub-pixels 52 in the pixel column may form the pixel pair 60. That is, every two second sub-pixels 52 in the pixel column may form the pixel pair 60. Each pixel column may include multiple pixel pairs 60. In each pixel pair 60, the anode via holes 21 corresponding to the two second sub-pixels 52 may be close to each other. No anode via hole 21 may be defined between two adjacent second sub-pixels 52 of adjacent pixel pairs 60. The two adjacent second sub-pixels 52 of adjacent pixel pairs 60 may be spaced apart by the spacer structure 80.

In some embodiments, as shown in FIG. 3, the pixel columns of the second sub-pixels 52 may at least include a first sub-pixel column 71 and a second sub-pixel column 72. The pixel pair 60 formed by any adjacent two second sub-pixels 52 in the first sub-pixel column 71 may be a first pixel pair 61. The pixel pair 60 formed by any adjacent two second sub-pixels 52 in the second sub-pixel column 72 may be a second pixel pair 62. Orthographic projections of the anode via holes 21 in the first pixel pair 61 and orthographic projections the anode via holes 21 in the second pixel pair 62 may be alternately arranged along the second direction X2. That is, the orthographic projections of the anode via holes 21 corresponding to the second sub-pixels 52 in the first pixel pair 61 may form a first projection pair, orthographic projections of the anode via holes 21 corresponding to the second sub-pixels 52 in the second pixel pair 62 may form a second projection pair, and the first projection pair and the second projection pair may be alternately arranged in the second direction X2. The pixel columns of the second sub-pixels 52 may further include multiple other pixel columns. The first sub-pixel column 71 and the second sub-pixel column 72 are described herein by way of example. In a case where the M-th pixel column is defined as the first sub-pixel column 71, then the (M+2)-th pixel column may be defined as the second sub-pixel column 72. In a case where the anode via holes 21 in the second sub-pixel column 72 are located between the N-th pixel row and (N+2)-th pixel row, then the anode via holes 21 in the first sub-pixel column 71 may be located between the (N+2)-th pixel row and (N+4)-th pixel row. In this way, the orthographic projections of the anode via holes 21 in the first pixel pair 61 and the orthographic projections the anode via holes 21 in the second pixel pair 62 may be alternately arranged along the second direction X2.

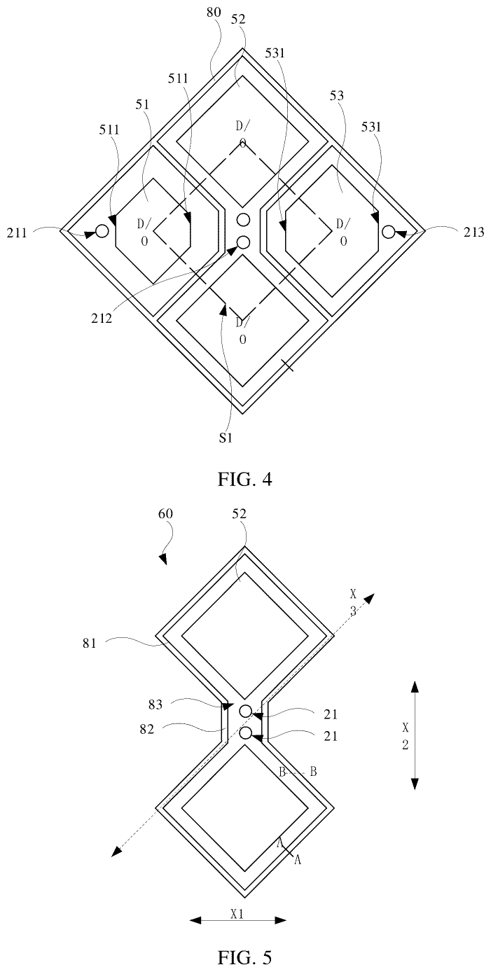

In some embodiments, as shown in FIG. 4, the anode via hole 21 corresponding to each first sub-pixel 51 may be a first via hole 211, the anode via hole 21 corresponding to each second sub-pixel 52 may be a second via hole 212, and the anode via hole 21 corresponding to each third sub-pixel 53 may be a third via hole 213. Each first via hole 211 may be configured to electrically connect the corresponding first sub-pixel 51 to the driving substrate 10 to drive the corresponding first sub-pixel 51 to emit light. Each second via hole 212 may be configured to electrically connect the corresponding second sub-pixel 52 to the driving substrate 10 to drive the corresponding second sub-pixel 52 to emit light. Each third via hole 213 may be configured to electrically connect the corresponding third sub-pixel 53 to the driving substrate 10 to drive the corresponding third sub-pixel 53 to emit light. In the first direction X1, each first sub-pixel 51 may form a first plane 511 on each of a side near the second via hole 212 and a side away from the second via hole 212, each third sub-pixel 53 may form a second plane 531 on each of a side near the second via hole 212 and a side away from the second via hole 212. The first via hole 211 may be defined outside the first plane 511 of the first sub-pixel 51 on the side away from the second via hole 212. The third via hole 213 may be disposed outside the second plane 531 of the third sub-pixel 53 on the side away from the second via hole 212. In this way, both the first sub-pixels 51 and the third sub-pixels 53 may be chamfered to protect the corresponding anode via holes 21, and further reduce the waste of pixel aperture.

In some embodiments, as shown in FIG. 4, each second sub-pixel 52 may be substantially quadrilateral in shape. Each first sub-pixel 51 and each third sub-pixel 53 may be substantially hexagonal in shape.

In some embodiments, as shown in FIGS. 3 and 4, the display panel may further include the spacer structure 80. The spacer structure 80 may be disposed between the first sub-pixels 51, the second sub-pixels 52, and the third sub-pixels 53. The spacer structure 80 may be configured to space the first sub-pixels 51, the second sub-pixels 52, and the third sub-pixels 53 apart from each other. The spacer structure 80 may be a suspended structure in the shape of a “mushroom cap”, which may serve as a shield during the deposition. In some embodiments, the spacer structure 80 may include a metal layer 801 and an insulating layer 802. The metal layer 801 may be disposed on the pixel defining layer 30. The insulating layer 802 may be disposed on the metal layer 801. A width of the insulating layer 802 may be greater than a width of the metal layer 801.

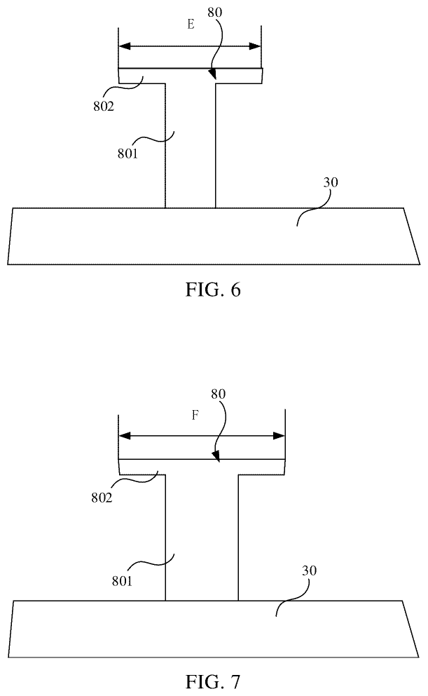

In some embodiments, as shown in FIGS. 6 and 7, FIG. 6 is a schematic structural sectional view of a spacer structure 80 at A-A in FIG. 5, and FIG. 7 is a schematic structural sectional view of a spacer structure 80 at B-B in FIG. 5. FIG. 6 may be a schematic structural sectional view perpendicular to the diagonal direction X3. FIG. 7 may be a schematic structural sectional view parallel to the first direction X1. It may be observed from FIGS. 6 and 7 that due to the adoption of the diamond arrangement structure, a width of the spacer structure 80 in FIG. 6 may be E, and a width of the spacer structure 80 in FIG. 7 may be F, where E may be less than F.

In some embodiments, as shown in FIG. 4, the pixel pair 60, the first sub-pixel 51, and the third sub-pixel 53 may be respectively located at the vertices D of the virtual rhombus S1. The center points O of the second sub-pixels 52, the center point O of first sub-pixel 51, and the center point O of third sub-pixel 53 may each coincide with a respective vertex D of the virtual rhombus S1. Within each virtual rhombus S1, there may be one first sub-pixel 51, two second sub-pixels 52, and one third sub-pixel 53. The center point O of the corresponding first sub-pixel 51, the center points O of the corresponding second sub-pixels 52, and the center point O of the corresponding third sub-pixel 53 may be located at the intersections of the diagonals. The center point O of the corresponding first sub-pixel 51, the center points O of the corresponding second sub-pixels 52, and the center point O of corresponding third sub-pixel 53 may be located at different vertices D of the virtual rhombus S1. Through the above design, the aperture ratio of each of the first sub-pixel 51, the second sub-pixel 52, and the third sub-pixel 53 may be reduced, thereby improving the image display quality of the display.

In some embodiments, as shown in FIG. 4, within each virtual rhombus S1, the corresponding first sub-pixel 51, the corresponding second sub-pixels 52, and the corresponding third sub-pixel 53 may share the second sub-spacer structure 82. Multiple identical virtual rhombuses S1 may be defined in the display panel, where the first sub-pixel 51, the second sub-pixels 52, and the third sub-pixel 53 within each virtual rhombus S1 may share the second sub-spacer structure 82. As a result, the uniformity of display may be improved.

In some embodiments of the present disclosure, on one hand, the anode via holes 21 corresponding to the two second sub-pixels 52 in the pixel pair 60 may be positioned close to each other, and no spacer structure 80 may be disposed between the two corresponding anode via holes 21, thereby allowing portions of the pixel region 31 where the two second sub-pixels 52 are located to be in communication with each other. Since there may be no spacer structure 80 between the second sub-pixels 52 in the pixel pair 60, the second sub-pixels 52 may be in communication with each other, and the anode via holes 21 may be disposed at positions where the two second sub-pixels 52 are in communication, thereby reducing waste in the pixel region and achieving the maximum pixel aperture ratio while ensuring display performance. On the other hand, the second sub-spacer structures 82 may be connected respectively to the edges of the corresponding first sub-spacer structures 81 to communicate the two first sub-spacer structures 81, so that no spacer structure 80 may be needed between the two anode via holes 21 to provide separation. In addition, the second sub-spacer structure 82 located on both sides of the anode via holes 21 that separates the anode via holes 21 may be a substantially linear spacer structure 80, which may result in a relatively long cathode overlap distance. Within the virtual rhombus S1, the first sub-pixel 51, the second sub-pixels 52, and the third sub-pixel 53 may all share the second sub-spacer structures 82, thereby improving the uniformity of display.

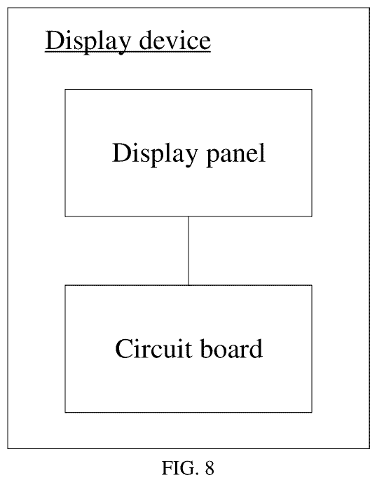

Some embodiments of the present disclosure may further provide a display device. As shown in FIG. 8, FIG. 8 is a schematic structural sectional view of a display device according to some embodiments of the present disclosure. The display device may include the display panel mentioned above and a circuit board electrically connected to the display panel.

In the present disclosure, unless otherwise explicitly specified or defined, terms such as “disposed,” “connected,” etc., should be interpreted broadly. For example, a connection may be fixed or detachable, or integrated; it may be a mechanical connection, an electrical connection, or a direct connection, or it may be indirectly connected through an intermediary, or it may refer to the internal communication or interaction between two components. Those skills in the art may understand the specific meanings of the above terms in the present disclosure based on the context.

In the description of this specification, references to terms such as “some embodiments” mean that the specific features, structures, materials, or characteristics described in connection with the embodiment are included in at least one embodiment of the present disclosure. In this specification, the schematic descriptions of the above terms do not necessarily refer to the same embodiment or example. Moreover, the described specific features, structures, materials, or characteristics may be combined in any suitable manner in one or more embodiments or examples. Furthermore, without contradiction, those skills in the art may combine and integrate the different embodiments or examples described in this specification, as well as the features of different embodiments or examples.

Although the embodiments of the present disclosure have been shown and described above, it should be understood that the above embodiments are exemplary and should not be construed as limiting the present disclosure. Those skills in the art may make variations, modifications, substitutions, and adaptations to the above embodiments within the scope of the present disclosure. Therefore, any changes or modifications made in accordance with the claims and the description of the present disclosure shall fall within the scope of the patent protection of the present disclosure.

1. A display panel, comprising:
a driving substrate;
a planarization layer, disposed on the driving substrate;
a pixel defining layer, disposed on the planarization layer and defining a pixel region, wherein a plurality of anode via holes are defined on the planarization layer in a radial direction of the pixel region;
a plurality of anodes, each being disposed in the pixel region and extending toward a corresponding one of the plurality of anode via holes, wherein each of the plurality of anodes is electrically connected to the driving substrate through the corresponding one of the plurality of anode via holes;
a plurality of sub-pixels, disposed in the pixel region and comprising first sub-pixels, second sub-pixels, and third sub-pixels, wherein the first sub-pixels, the second sub-pixels, and the third sub-pixels are disposed in a first direction and a second direction; and
a spacer structure, disposed on the pixel defining layer, protruding toward a side away from the driving substrate, and configured to space the first sub-pixels, the second sub-pixels, and the third sub-pixels apart from each other;
wherein in the second direction, adjacent two of the second sub-pixels in a same pixel column form a pixel pair, and in the pixel pair, the anode via hole corresponding to any one of the second sub-pixels is located on a side of the one of the second sub-pixels that is adjacent to the other one of the second sub-pixels;
wherein within the pixel pair, the spacer structure comprises two first sub-spacer structures and two sub-second spacer structures, each of the two first sub-spacer structures is disposed on an outer peripheral side of a corresponding one of the two second sub-pixels, and a connection hole is defined on a side of each of the two first sub-spacer structures that is adjacent to the corresponding anode via hole; and
wherein the two second sub-spacer structures are connected to the two first sub-spacer structures to interconnect the connection holes of the two first sub-spacer structures, and the anode via hole corresponding to each of the second sub-pixels in the pixel pair is located between the two second sub-spacer structures.

2. The display panel as claimed in claim 1, wherein in the first direction, the second sub-pixels are arranged at intervals to form a first pixel row, the first sub-pixels and the third sub-pixels are alternately arranged at intervals to form a second pixel row, and in the second direction, the first pixel row and the second pixel row are alternately arranged at intervals; and
in the second direction, the second sub-pixels are arranged at intervals to form a first pixel column, the first sub-pixels and the third sub-pixels are alternately arranged at intervals to form a second pixel column, and in the first direction, the first pixel column and the second pixel column are alternately arranged at intervals.

3. The display panel as claim in claim 1, wherein pixel columns of the second sub-pixels at least comprises a first sub-pixel column and a second sub-pixel column, the pixel pair formed by adjacent two of the second sub-pixels in the first sub-pixel column is a first pixel pair, the pixel pair formed by adjacent two of the second sub-pixels in the second sub-pixel column is a second pixel pair, and orthographic projections of the anode via holes corresponding to the second sub-pixels in the first pixel pair and orthographic projections of the anode via holes corresponding to the second sub-pixels in the second pixel pair are alternately arranged in the second direction.

4. The display panel as claim in claim 1, wherein the anode via hole corresponding to each of the first sub-pixels is a first via hole, the anode via hole corresponding to each of the second sub-pixels is a second via hole, and the anode via hole corresponding to each of the third sub-pixels is a third via hole;
in the first direction, each of the first sub-pixels forms a first plane on each of a side close to the second via hole and a side away from the second via hole, and each of the third sub-pixels forms a second plane on each of a side close to the second via hole and a side away from the second via hole; and
the first via hole is defined outside the first plane of the first sub-pixel on the side away from the second via hole, and the third via hole is defined outside the second plane of the third sub-pixel on the side away from the second via hole.

5. The display panel as claim in claim 4, wherein each of the first sub-pixels and each of the third sub-pixels are substantially hexagonal in shape, and each of the second sub-pixels is substantially quadrilateral in shape.

6. The display panel as claim in claim 1, wherein the display panel comprises more than one virtual rhombus, each virtual rhombus comprises one of the first sub-pixels, two of the second sub-pixels that are adjacent to the one of the first sub-pixels, and one of the third sub-pixels that is adjacent to the one of the first sub-pixels;
in each virtual rhombus, the corresponding two of the second sub-pixels, the corresponding one of the first sub-pixels, and the corresponding one of the third sub-pixel are respectively located at vertices of the virtual rhombus, and center points of the corresponding two of the second sub-pixels, a center point of the corresponding one of the first sub-pixels, and a center point of the corresponding one of the third sub-pixels coincide with the vertices of the virtual rhombus.

7. The display panel as claim in claim 6, wherein within each virtual rhombus, the corresponding one of the first sub-pixels, the corresponding two of the second sub-pixels, and the corresponding one of the third sub-pixels share the two second sub-spacer structures;
wherein the two second spacer structures are substantially linear.

8. The display panel as claim in claim 1, wherein a material of the pixel defining layer comprises an inorganic material, the pixel defining layer extends along the anode via holes and the planarization layer, and an orthographic projection of the spacer structure on the driving substrate and orthographic projections of the anode via holes on the driving substrate are non-overlapped.

9. The display panel as claim in claim 1, wherein the spacer structure comprises a metal layer and an insulating layer, the metal layer is disposed on the pixel defining layer, the insulating layer is disposed on the metal layer, and a width of the insulating layer is greater than a width of the metal layer.

10. The display panel as claim in claim 1, wherein a diagonal direction exists between the first direction and the second direction, and a width of a cross-section of the spacer structure along a direction perpendicular to the diagonal direction is smaller than a width of a cross-section of the spacer structure along a direction parallel to the first direction.

11. A display device, comprising:
a display panel, comprising:
a driving substrate;
a planarization layer, disposed on the driving substrate;
a pixel defining layer, disposed on the planarization layer and defining a pixel region, wherein a plurality of anode via holes are defined on the planarization layer in a radial direction of the pixel region;
a plurality of anodes, each being disposed in the pixel region and extending toward a corresponding one of the plurality of anode via holes, wherein each of the plurality of anodes is electrically connected to the driving substrate through the corresponding one of the plurality of anode via holes;
a plurality of sub-pixels, disposed in the pixel region and comprising first sub-pixels, second sub-pixels, and third sub-pixels, wherein the first sub-pixels, the second sub-pixels, and the third sub-pixels are disposed in a first direction and a second direction; and
a spacer structure, disposed on the pixel defining layer, protruding toward a side away from the driving substrate, and configured to space the first sub-pixels, the second sub-pixels, and the third sub-pixels apart from each other;
wherein in the second direction, adjacent two of the second sub-pixels in a same pixel column form a pixel pair, and in the pixel pair, the anode via hole corresponding to any one of the second sub-pixels is located on a side of the one of the second sub-pixels that is adjacent to the other one of the second sub-pixels;
wherein within the pixel pair, the spacer structure comprises two first sub-spacer structures and two sub-second spacer structures, each of the two first sub-spacer structures is disposed on an outer peripheral side of a corresponding one of the two second sub-pixels, and a connection hole is defined on a side of each of the two first sub-spacer structures that is adjacent to the corresponding anode via hole; and
wherein the two second sub-spacer structures are connected to the two first sub-spacer structures to interconnect the connection holes of the two first sub-spacer structures, and the anode via hole corresponding to each of the second sub-pixels in the pixel pair is located between the two second sub-spacer structures; and
a circuit board, electrically connected to the display panel.

12. The display device as claimed in claim 11, wherein in the first direction, the second sub-pixels are arranged at intervals to form a first pixel row, the first sub-pixels and the third sub-pixels are alternately arranged at intervals to form a second pixel row, and in the second direction, the first pixel row and the second pixel row are alternately arranged at intervals; and
in the second direction, the second sub-pixels are arranged at intervals to form a first pixel column, the first sub-pixels and the third sub-pixels are alternately arranged at intervals to form a second pixel column, and in the first direction, the first pixel column and the second pixel column are alternately arranged at intervals.

13. The display device as claimed in claim 11, wherein pixel columns of the second sub-pixels at least comprises a first sub-pixel column and a second sub-pixel column, the pixel pair formed by adjacent two of the second sub-pixels in the first sub-pixel column is a first pixel pair, the pixel pair formed by adjacent two of the second sub-pixels in the second sub-pixel column is a second pixel pair, and orthographic projections of the anode via holes corresponding to the second sub-pixels in the first pixel pair and orthographic projections of the anode via holes corresponding to the second sub-pixels in the second pixel pair are alternately arranged in the second direction.

14. The display device as claimed in claim 11, wherein the anode via hole corresponding to each of the first sub-pixels is a first via hole, the anode via hole corresponding to each of the second sub-pixels is a second via hole, and the anode via hole corresponding to each of the third sub-pixels is a third via hole;
in the first direction, each of the first sub-pixels forms a first plane on each of a side close to the second via hole and a side away from the second via hole, and each of the third sub-pixels forms a second plane on each of a side close to the second via hole and a side away from the second via hole; and
the first via hole is defined outside the first plane of the first sub-pixel on the side away from the second via hole, and the third via hole is defined outside the second plane of the third sub-pixel on the side away from the second via hole.

15. The display device as claimed in claim 14, wherein each of the first sub-pixels and each of the third sub-pixels are substantially hexagonal in shape, and each of the second sub-pixels is substantially quadrilateral in shape.

16. The display device as claimed in claim 11, wherein the display panel comprises more than one virtual rhombus, each virtual rhombus comprises one of the first sub-pixels, two of the second sub-pixels that are adjacent to the one of the first sub-pixels, and one of the third sub-pixels that is adjacent to the one of the first sub-pixels;
in each virtual rhombus, the corresponding two of the second sub-pixels, the corresponding one of the first sub-pixels, and the corresponding one of the third sub-pixel are respectively located at vertices of the virtual rhombus, and center points of the corresponding two of the second sub-pixels, a center point of the corresponding one of the first sub-pixels, and a center point of the corresponding one of the third sub-pixels coincide with the vertices of the virtual rhombus.

17. The display device as claimed in claim 16, wherein within each virtual rhombus, the corresponding one of the first sub-pixels, the corresponding two of the second sub-pixels, and the corresponding one of the third sub-pixels share the two second sub-spacer structures;
wherein the two second spacer structures are substantially linear.

18. The display device as claimed in claim 11, wherein a material of the pixel defining layer comprises an inorganic material, the pixel defining layer extends along the anode via holes and the planarization layer, and an orthographic projection of the spacer structure on the driving substrate and orthographic projections of the anode via holes on the driving substrate are non-overlapped.

19. The display device as claimed in claim 11, wherein the spacer structure comprises a metal layer and an insulating layer, the metal layer is disposed on the pixel defining layer, the insulating layer is disposed on the metal layer, and a width of the insulating layer is greater than a width of the metal layer.

20. A display panel, comprising:
a driving substrate;
a planarization layer, disposed on the driving substrate;
a pixel defining layer, disposed on the planarization layer and defining a pixel region, wherein a plurality of anode via holes are defined on the planarization layer in a radial direction of the pixel region;
a plurality of anodes, each being disposed in the pixel region and extending toward a corresponding one of the plurality of anode via holes, wherein each of the plurality of anodes is electrically connected to the driving substrate through the corresponding one of the plurality of anode via holes;
a plurality of sub-pixels, disposed in the pixel region and comprising first sub-pixels, second sub-pixels, and third sub-pixels, wherein the first sub-pixels, the second sub-pixels, and the third sub-pixels are disposed in a first direction and a second direction; and
a spacer structure, disposed on the pixel defining layer, protruding toward a side away from the driving substrate, and configured to space the first sub-pixels, the second sub-pixels, and the third sub-pixels apart from each other;
wherein in the second direction, adjacent two of the second sub-pixels in a same pixel column form a pixel pair, and in the pixel pair, the anode via hole corresponding to any one of the second sub-pixels is located on a side of the one of the second sub-pixels that is adjacent to the other one of the second sub-pixels;
wherein in the pixel pair, portions of the pixel region where the two second sub-pixels are located are in communication with each other, and the spacer structure located on both sides of the anode via holes corresponding to the two second sub-pixels are substantially linear.
